(19) United States
(12) Patent Application Publication
(10) Pub. No.: US 2016/0057866 A1
(43) Pub. Date: Feb. 25, 2016

(54) METAL FILM FORMING METHOD AND CONDUCTIVE INK USED IN SAID METHOD

(71) Applicant: JSR CORPORATION, Minato-ku (JP)

(72) Inventors: Sugirou SHIMODA, Minato-ku (JP); Kenzou Ookita, Minato-ku (JP); Isao Aritome, Minato-ku (JP); Kazuto Watanabe, Minato-ku (JP); Kenrou Tanaka, Minato-ku (JP)

(73) Assignee: JSR CORPORATION, Minato-ku (JP)

(21) Appl. No.: 14/463,012

(22) Filed: Aug. 19, 2014

(51) Int. Cl. H05K 3/00; H01L 23/48; H01L 21/768; H01L 27/108; H01L 23/532; C08K 5/17; H05K 1/09; H05K 1/02; C09D 11/52; C08K 5/098; C08K 3/22; C08K 5/07; H01B 13/00; H01L 21/288

(52) U.S. Cl. CPC H05K 3/0091; H01B 13/0026; H01L 23/481; H01L 21/76898; H01L 27/1085; H01L 27/10805; H01L 23/53228; H01L 21/288; H05K 1/097; H05K 1/0298; C09D 11/52; C08K 5/098; C08K 3/22; C08K 5/07; C08K 5/17; H05K 2201/09509; C08K 2003/2248

(57) ABSTRACT

An object of the invention is to provide a simple method capable of easily forming a metal film on a surface of a perforated substrate that is adjacent to the hole in the substrate. The metal film forming method includes a step of heating a perforated substrate having a hole while a surface of the substrate adjacent to the hole is in contact with a conductive ink containing a metal salt and a reducing agent.

### BACKGROUND OF THE INVENTION

1. Field of the Invention

The present invention relates to a method for forming a metal film on a surface of a perforated substrate that is adjacent to the hole in the substrate, to a conductive ink used in the method, and to a multilayer wiring board, a semiconductor substrate and a capacitor cell.

2. Description of the Related Art

In printed wiring boards used in devices such as electronic devices, wiring layers are conductively connected together via metal films formed on the inner surface in bottomed via holes that have an opening on one side and a blocked end on the other side (hereinafter, such via holes will be also written as the “blind vias”). Such metal films are formed by, for example, plating the perforated substrates or filling the via holes with a conductive paste.

For example, a conductive paste is applied into the blind vias with use of a squeegee (see, for example, Patent Literatures 1 and 2). The boards obtained by such a method are thereafter processed by techniques such as etching to form wiring boards having wiring patterns on both sides, and a plurality of such double-sided wiring boards are stacked to produce multilayer wiring boards.

Increasing the wiring density in the multilayer wiring boards requires that the wiring patterns have finer designs and a larger number of layers be interconnected through via holes. The vias have to be small in diameter in order to establish a connection between fine wiring patterns. While the blind vias do not require large lands, this problem needs to be addressed.

Electrical connection may be established more reliably when the holes to be filled with a conductive paste are through holes. However, it is difficult for a viscous paste to completely fill a bottomed blind via having a small diameter without leaving any spaces inside. Consequently, bubbles may be trapped at times. Thus, the reliable filling of via holes with a conductive paste is difficult, and the air trapped in the via holes problematically causes connection failure.

Further, conductive pastes have low conductivity compared to metallic copper and are difficult to achieve a sufficient electrical connection when applied into small-diameter blind vias. Because of these facts, the use of conductive pastes is not necessarily an effective approach to reducing the size and increasing the wiring density of printed wiring boards.

On the other hand, electroless metal plating compares favorably to the application of a conductive paste in view of the fact that blind vias may be filled with a metal deposit having high conductivity. However, this method has serious problems in productivity because of the need of complicated treatments such as adding a catalyst to the inner surface in the via holes in order to facilitate the formation of plating layers, and also because of the low rate of the precipitation of the plating films. In the case of electroplating, great difficulties are encountered in depositing platings only onto the blocked ends of blind vias. The implementation of such an electroplating treatment with respect to the blocked ends of blind vias while electrically isolating the other portions entails very complicated additional steps (see, for example, Patent Literature 3).

Solid-state imaging devices used in apparatuses such as mobile phones include a semiconductor substrate having a sensor chip in a central area of the surface, and a glass substrate fixed on the semiconductor substrate. On the backside of the semiconductor substrate, external electrodes such as solder balls are formed. These external electrodes are electrically connected to the sensor chip in a central area of the surface of the semiconductor substrate, via through electrodes formed in the semiconductor substrate by a through silicon via (TSV) technique (see, for example, Patent Literature 4) The through electrodes are frequently formed by a film production method such as, for example, a sputtering method. However, the sputtering method has problems in that the treatment entails high vacuum and involves expensive apparatuses.

### CITATION LIST

### Patent Literature

[Patent Literature 1] JP-A-2002-144523

[Patent Literature 2] JP-A-2004-039887

[Patent Literature 3] JP-A-2000-068651

[Patent Literature 4] JP-A-2011-205222

### SUMMARY OF THE INVENTION

An object of the invention is to provide a simple method capable of easily forming a metal film on a surface of a perforated substrate that is adjacent to the hole in the substrate, and to provide a conductive ink used in the metal film forming method.

The present inventors carried out extensive studies to solve the problems mentioned above. As a result, the present inventors have found that the aforementioned problems can be solved by a metal film forming method and a conductive ink having the following configurations. The present invention has been completed based on the finding.

For example, the present invention resides in the following [1] to [19].

[1] A metal film forming method including a step of heating a perforated substrate having a hole while a surface of the substrate adjacent to the hole is in contact with a conductive ink containing a metal salt and a reducing agent.

[2] The metal film forming method described in [1], wherein the viscosity of the conductive ink is not more than 1 Pa·s.

[3] The metal film forming method described in [1] or [2], wherein the substrate has a bottomed hole having an opening on one side and a blocked end on the other side.

[4] The metal film forming method described in [3], wherein the substrate is a stack including a plurality of layers, the opening is defined by a through hole disposed in a first layer, and the blocked end is defined by a second layer.

[5] The metal film forming method described in [3] or [4], wherein the diameter of the opening is 1 to 1000 μm.

[6] The metal film forming method described in any one of [1] to [5], wherein the substrate has at least one electrode formed adjacent to the hole.

[7] The metal film forming method described in any one of [1] to [6], wherein the metal salt is a copper salt.

[8] The metal film forming method described in [7], wherein the copper salt is at least one selected from copper formate and copper formate tetrahydrate.

[9] The metal film forming method described in any one of [1] to [8], wherein the reducing agent is at least one selected from alkanethiols, amines, hydrazines, monoalcohols, diols, hydroxylamines, α-hydroxyketones and carboxylic acids.

[10] The metal film forming method described in any one of [1] to [9], wherein the conductive ink further contains a solvent.

[11] The metal film forming method described in any one of [1] to [10], wherein the heating is performed in a non-oxidizing atmosphere at a temperature in the range of 50° C. to 500° C.

[12] The metal film forming method described in any one of [1] to [11], wherein the conductive ink is brought into contact with the surface of the substrate adjacent to the hole by a coating method or a printing method.

[13] The metal film forming method described in any one of [1] to [12], wherein the hole is a via hole formed in a multilayer wiring board, a through silicon via formed in a semiconductor substrate, or a via hole formed in a multilayer wiring layer stacked on a semiconductor substrate.

[14] The metal film forming method described in any one of [1] to [12], wherein the metal film is a capacitor electrode for constituting a capacitor cell of a dynamic random access memory.

[15] A conductive ink including a metal salt and a reducing agent, wherein the conductive ink is used in the metal film forming method described in any one of [1] to [14].

[16] The conductive ink described in [15], having a viscosity of not more than 1 Pa·s.

[17] A multilayer wiring board having a metal film on a surface adjacent to a via hole, the metal film being formed from the conductive ink described in [15] or [16].

[18] A semiconductor substrate having a metal film on a surface adjacent to a through silicon via disposed in the semiconductor substrate or on a surface adjacent to a via hole disposed in a multilayer wiring layer stacked on the semiconductor substrate, the metal film being formed from the conductive ink described in [15] or [16].

[19] A capacitor cell of a dynamic random access memory, having a capacitor electrode formed from the conductive ink described in [15] or [16].

According to the metal film forming method of the present invention, a metal film can be formed simply and easily on a surface of a perforated substrate that is adjacent to the hole in the substrate. The inventive conductive ink can be suitably used in the metal film forming method. With the metal film forming method and the conductive ink of the present invention, for example, a plurality of electrodes can be connected together with high conduction reliability.

### BRIEF DESCRIPTION OF THE DRAWINGS

FIG. 1 is a schematic sectional view illustrating a first example of the metal film forming method of the present invention.

FIG. 2 is a schematic sectional view illustrating a second example of the metal film forming method of the present invention.

FIGS. 3A to 3G illustrate steps in Example B1 in the present invention.

FIGS. 4A to 4F illustrate steps in Example B2 in the present invention.

FIGS. 5A to 5E illustrate steps in Example B3 in the present invention.

FIG. 6 is a schematic sectional view illustrating a hole formed in a substrate.

### DESCRIPTION OF THE PREFERRED EMBODIMENTS

The present invention relates to a method for forming a metal film on a surface of a perforated substrate that is adjacent to the hole in the substrate with use of a conductive ink, and to a conductive ink used in the method. In the specification, electrically conductive parts such as wires, electrodes and terminals in the fields of wiring boards and circuit boards will be collectively referred to as “electrodes” for convenience hereinafter.

### [Metal Film Forming Method]

The metal film forming method of the invention includes a step of heating a perforated substrate having a hole while a surface of the substrate adjacent to the hole is in contact with a conductive ink containing a metal salt and a reducing agent. The step results in a metal film formed on the surface of the substrate.

### [Perforated Substrates]

Examples of the substrates include polyester films, polyimide films, Bakelite substrates, glass substrates, glass epoxy substrates, and semiconductor substrates such as semiconductor wafers and semiconductor chips. In the specification, the term “substrates” includes multilayer wiring boards composed of a core substrate having features such as wiring circuits, and layers such as interlayer dielectrics and wiring layers stacked on the core substrate.

The holes in the perforated substrates may be through holes or bottomed holes. According to the invention, metal films having strong adhesion to the substrate surface adjacent to the holes, even in the case of bottomed holes, can be formed by the simple method.

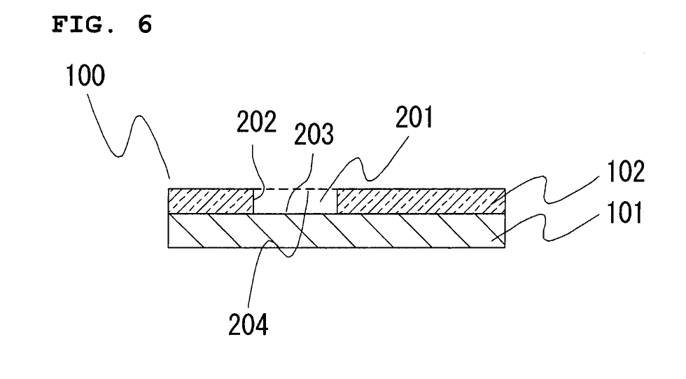

The surface of the substrate that is exposed on the lateral side adjacent to the hole (the space) will be also written simply as the “sidewall in the hole”. In the case of a bottomed hole, the surface of the substrate that is exposed at the blocked end adjacent to the hole (the space), for example, a land surface, will be also written simply as the “bottom in the hole”. The whole of the sidewall and the bottom in the hole will be also written as the “inner surface in the hole”. For example, FIG. 6 illustrates a cross section of an example of the perforated substrates, in which a substrate 100 is composed of a core substrate 101 and an insulating layer 102, and a hole 201 reaching the core substrate 101 is formed in the insulating layer 102. Here, numeral 202 indicates the sidewall in the hole 201, and numeral 203 indicates the bottom in the hole 201.

An example of the holes in the perforated substrates is a bottomed hole formed in the substrate which has an opening on one side and a blocked end on the other side. The “opening” is a region defined by a line segment of the substrate surface on the open side intersecting with the sidewall in the hole. This region is indicated by a dotted line with numeral 204 in FIG. 6. The “blocked end” is indicated by numeral 203 in FIG. 6.

When, for example, the substrate is a stacked substrate including a first layer and a second layer, the opening of the hole may be defined by a through hole disposed in the first layer, namely, one end of the through hole, and the blocked end of the hole may be defined by the second layer, namely, the second layer blocking the other end of the through hole in the first layer.

The first layer and the second layer may be any of the known substrates described above as examples, or may be any other layers such as insulating layers. For example, the first layer and the second layer may be stacked one on top of the other by a bonding method involving a bonding layer (via a bonding layer), or may be stacked together by lamination with a laminating machine such as a vacuum laminator.

The bonding layers are not particularly limited, and examples thereof include layers made of epoxy resins, urethane resins and other known adhesives. The bonding layers may be formed by, for example, coating or printing with a dispenser, or dry lamination.

The substrate may have at least one electrode formed adjacent to the hole. For example, the electrodes may be formed by etching a metal foil laminated on the substrate, coating or printing the conductive ink used in the invention, or coating or printing other known conductive ink. Examples of the metal foils include copper foils. Commercially available copper clad laminates may be used as the substrates having electrodes.

The shapes of the holes in the substrates are not particularly limited. Exemplary shapes of the cross section of holes perpendicular to the direction of the formation of the holes include circles, ellipses and squares. Examples of the shapes of the cross section of holes parallel to the direction of the formation of the holes include squares, triangles and trapezoids. The direction of the formation of the holes is usually the direction of the thickness of the substrate.

For example, the diameter of the opening of the hole may be in the range of 1 to 1000 In the interposer application, the diameter may be 10 to 1000 μm, and may be preferably 10 to 500 μm, and more preferably 10 to 200 μm from the viewpoint of increasing the wiring density in the wiring board. In the TSV application, the diameter is preferably 5 to 100 μm. The diameter of the opening indicates the average of the minimum value and the maximum value of the lengths of line segments connecting the edges of the opening through the gravity center of the opening.

The depth of the holes is not particularly limited and may be, for example, 10 to 100 μm.

The holes may be formed by methods such as carbon dioxide laser methods and mechanical drilling methods.

### [Contacting Step]

Examples of the methods for bringing the conductive ink into contact with the inner surface in the hole include coating and printing, specifically, printing such as ink jet printing, and coating with a dispenser, an injector, a curtain coater or a bar coater. In the specification, coating and printing will be sometimes collectively written as “application”. The conductive ink may be applied to the inner surface in the hole in one or more operations. To ensure that a metal film will be formed over the entirety of the inner surface in the hole, it is preferable that the hole be filled with the conductive ink at least to the opening of the hole.

Here, the conductive ink may be applied into the hole and also onto the plane surface of the substrate in order to form simultaneously an upper wiring layer, and a metal film on the inner surface in the hole that connects the wiring layer to a lower wiring layer.

Alternatively, an upper wiring layer (an electrode 1) and a lower wiring layer (an electrode 2) may be conductively connected to each other through a metal film formed on the inner surface in the hole in such a manner that the electrodes 1 and 2 to be connected through the metal film are formed first with a conductive ink, then the hole is formed in the prescribed position on the electrodes 1 and 2, and thereafter the conductive ink used in the invention is applied into the hole.

### [Heating Step]

The conductive ink which is in contact with the inner surface in the hole is heated to form a metal film so as to cover the inner surface in the hole. When a plurality of electrodes have been formed adjacent to the hole, these electrodes are electrically connected together through the metal film.

After the conductive ink has been brought into contact with the inner surface in the hole, the heating for the formation of a metal film is preferably performed in a non-oxidizing atmosphere. Examples of the non-oxidizing atmospheres include a nitrogen atmosphere, a helium atmosphere and an argon atmosphere. To enhance the treatment performance, the heat treatment may be performed with use of a continuous firing furnace such as a nitrogen reflow furnace. In particular, a nitrogen atmosphere is preferable as the non-oxidizing atmosphere because of the inexpensiveness of nitrogen gas. This configuration eliminates the need of creating a reducing atmosphere using a reducing gas such as hydrogen gas after the conductive ink is brought into contact with the inner surface in the hole. That is, the heating may take place under safe conditions to give the desired metal film.

The temperature of heating for forming the metal films is not particularly limited as long as, for example, the metal salt such as a copper salt is reduced and organic matters are decomposed or vaporized. For example, the heating temperature may be in the range of 50° C. to 500° C., preferably 120° C. to 360° C., and more preferably 120° C. to 260° C. For example, the heating temperature is preferably not less than 50° C., and more preferably not less than 120° C. to promote the reduction reaction of the metal salt such as a copper salt and also to prevent the occurrence of residual organic matters. The heating temperature is preferably not more than 500° C. In view of the fact that the electrodes to be connected together may be disposed on organic substrates, the heating temperature is preferably not more than 360° C., and more preferably not more than 260° C.

The time for which the conductive ink is heated is not particularly limited and may be selected appropriately in view of the type of the metal salt and the desired characteristics of the metal film. For example, the heating time may be in the range of 5 to 90 minutes, and preferably 10 to 60 minutes. When, for example, the heating temperature is approximately 300° C., the heating time is usually about 10 to 60 minutes. The heating time is usually about 10 to 70 minutes when the heating temperature is around 250° C.

When the ink is applied to the inner surface in the hole several times, a metal film having lower resistivity may be formed by repeating steps in which the conductive ink is applied and heated in a non-oxidizing atmosphere to form a metal film and thereafter the conductive ink is applied again and heated in a non-oxidizing atmosphere.

By the metal film forming method of the invention, a structure, for example, a multilayer wiring board can be obtained in which a metal film is formed on the inner surface (for example, the sidewall and the bottom) in the hole in the perforated substrate. For example, the thickness of the metal film may be 0.05 to 2 μm. In order to obtain physical strength and conduction properties, the thickness of the metal film is preferably not less than 0.1 μm.

According to the metal film forming method of the invention, a uniform metal film can be formed easily even on the sidewall in the hole. According to the invention, such uniform metal films may be formed without the need of high vacuum or expensive apparatuses in contrast to, for example, a sputtering method.

In the case where the hole coated with the metal film is to be filled to ensure high conduction reliability, for example, the hole may be filled with a resin or by electroplating. In the case of electroplating, the metal film formed by the metal film forming method of the invention may be used as a plating electrode.

As will be described later, the conductive ink used in the metal film forming method of the invention can realize strong adhesion between the metal film formed by the reduction reaction, and electrodes connected together through the metal film. In contrast to highly viscous pastes which are difficult to fill blind vias without trapping bubbles, the conductive ink used in the invention has lower viscosity than pastes and thus can be applied into the vias without trapping bubbles inside. As a result, the inventive method involving the conductive ink allows electrodes to be connected together with higher conduction reliability as compared to when other materials such as pastes are used.

[symbol]

Examples of Applications of Metal Film Forming Method

[symbol]

The metal film forming method of the present invention may be applied to the following examples.

(1) The formation of metal films for electrically connecting upper electrodes to lower electrodes in multilayer wiring boards. Such metal films are formed on the inner surface in via holes such as through via holes for connecting which penetrate all the layers, blind via holes for connecting the top layer to an inner layer, and buried via holes for connecting inner layers other than the top layer to each other.
(2) The formation of metal films on the inner surface in through silicon vias (TSV) in semiconductor substrates such as semiconductor wafers and chips. Through silicon vias (TSV) are formed throughout the thickness of semiconductor substrates in, for example, solid-state imaging devices such as CMOS image sensors, in order to establish an electrical connection between wiring circuits formed on the semiconductor substrates and external electrodes such as solder balls formed on the backside of the semiconductor substrates. Metal films may be formed as through electrodes on the inner surface in the vias by the inventive method.
(3) The formation of metal films for electrically connecting upper electrodes and lower electrodes, in via holes disposed in multilayer wiring layers stacked on semiconductor substrates such as semiconductor wafers and chips.
(4) The formation of capacitor electrodes that constitute capacitor cells of dynamic random access memories (DRAM). For example, metal films may be formed as capacitor electrodes by the inventive method on the inner surface in holes formed in insulating layers on semiconductor substrates.

Hereinbelow, specific examples of the inventive metal film forming method will be described with reference to the accompanying drawings.

[symbol]

First Example of Metal Film Forming Method

[symbol]

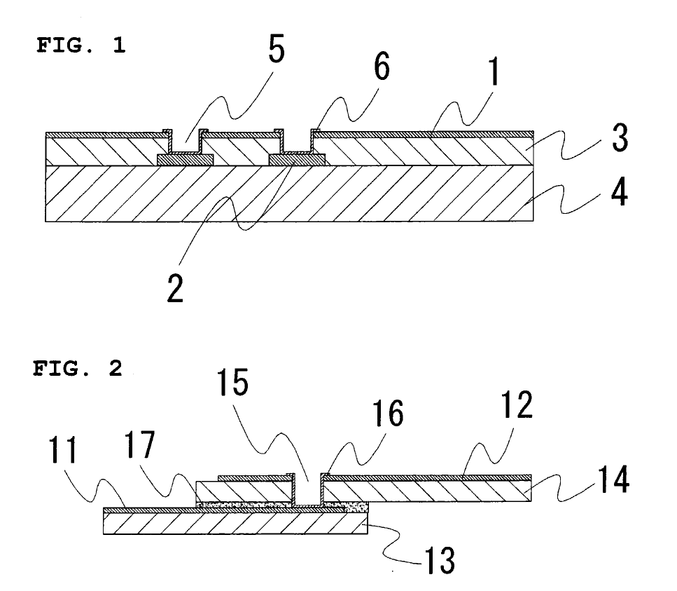

FIG. 1 is a schematic sectional view illustrating a first example of the metal film forming method of the present invention.

The first example of the inventive metal film forming method will be described with reference to FIG. 1.

A first electrode 1 is disposed on a first substrate 3, and a second electrode 2 is disposed on a second substrate 4. A via hole 5 extends through the first electrode 1 and the first substrate 3. That is, the opening of the via hole 5 is adjacent to the first electrode 1, and the surface of the second electrode 2 exposed as a result of the perforation defines the blocked end of the via hole 5, namely, the bottom in the via hole 5. The sidewall in the via hole 5 is defined by the sidewall in the through hole formed in the first electrode 1 and the first substrate 3.

For example, the first substrate 3 and the second substrate 4 may be joined together by lamination with a laminating machine such as a vacuum laminator. In this case, the first substrate 3 and the second substrate 4 are stacked such that the surface of the first substrate 3 which is or will be free from the first electrode 1 is opposed to the surface of the second substrate 4 on which the second electrode 2 is formed.

Here, the first electrode 1 and the second electrode 2 may be formed by, for example, etching metal foils laminated on the substrates 3 and 4, applying the conductive ink used in the invention, or applying other known conductive ink. Examples of the metal foils include copper foils. Commercially available copper clad laminates may be used as the substrates having electrodes.

The substrates 3 and 4 are not particularly limited, and examples thereof include polyester films, polyimide films, Bakelite substrates, glass substrates and glass epoxy substrates. The thickness of the substrates is not particularly limited, but may be 10 to 1000 μm, and preferably 10 to 100 μm.

There may be no first electrode 1 originally disposed on the first substrate 3. In this case, an appropriate electrode may be formed by the application of a conductive ink onto the first substrate 3, for example, after the first substrate 3 and the second substrate 4 have been joined together. Here, the first electrode 1 may be formed before the formation of the via hole 5 or after the formation of the via hole 5.

The types of the first electrode and the second electrode, and the types of the first substrate and the second substrate may be the same or different from each other. Examples of the combinations of the substrates include flexible printed circuit (FPC)/glass epoxy substrate, FPC/printed circuit board (PCB), and FPC/FPC. The substrates and the electrodes may be subjected to pretreatments such as washing, roughening and formation of fine irregularities as required.

In the first example of the metal film forming method, a point is determined in which the region where the first electrode 1 is formed is adjacent to or overlaps, in the direction of the thickness of the substrate, with the region where the second electrode 2 is formed (hereinafter, this point is also written as the “electrical connection point”), and the first substrate 3 is perforated with a prescribed diameter at least to a depth reaching the second electrode 2 to form the via hole 5. At this stage, the second electrode 2 is exposed in the via hole 5. Organic matters (smears) such as resins attached to the exposed surface of the second electrode 2 are preferably removed (desmeared) with agents such as permanganic acid. In the first example, the diameter of the opening of the via hole 5 is preferably larger than the thickness of the first substrate 3.

In the first example of the metal film forming method, the conductive ink used in the invention is applied to the via hole 5. By being heated, the conductive ink forms a metal film 6 covering the inner surface in the via hole 5. The conductive ink may be applied to the via hole 5 by any method without limitation, for example, with use of a dispenser, an injector or a bar coater. In the first example, as illustrated in FIG. 1, the conductive ink is applied so as to cover at least a portion of the first electrode 1, to cover the exposed second electrode 2 serving as the blocked end, and to cover the sidewall in the via hole 5; and the inner surface in the via hole 5 applied with the conductive ink is heated to form the metal film 6 that serves as a conduction portion covering the inner surface in the via hole 5. The metal film 6 electrically connects the first electrode 1 to the second electrode 2.

As will be described later, the conductive ink for forming the metal film 6 in FIG. 1 is a reductive conductive ink containing a metal salt and a reducing agent. The metal film 6 obtained by heating the ink exhibits high adhesion with respect to electrodes and realizes low contact resistance. Consequently, according to the first example of the metal film forming method, the first electrode 1 and the second electrode 2 may be connected together with high reliability through the metal film 6 formed on the inner surface in the via hole 5.

[symbol]

Second Example of Metal Film Forming Method

[symbol]

FIG. 2 is a schematic sectional view illustrating a second example of the metal film forming method of the present invention.

The second example of the inventive metal film forming method will be described with reference to FIG. 2.

A first electrode 11 is disposed on a first substrate 13, and a second electrode 12 is disposed on a second substrate 14. The first substrate 13 and the second substrate 14 are fixed to each other through a bonding layer 17. A via hole 15 extends through the second electrode 12, the second substrate 14 and the bonding layer 17. That is, the opening of the via hole 15 is adjacent to the second electrode 12, and the surface of the first electrode 11 exposed as a result of the perforation defines the blocked end of the via hole 15, namely, the bottom in the via hole 15. The sidewall in the via hole 15 is defined by the sidewall in the through hole formed by penetrating the second electrode 12, the second substrate 14 and the bonding layer 17.

The first substrate 13 and the second substrate 14 may be joined together through the bonding layer 17 disposed in, for example, a portion of the region where the first electrode 11 is formed on the first substrate 13. In this case, the first substrate 13 and the second substrate 14 are stacked such that the surface of the second substrate 14 which is or will be free from the second electrode 12 is opposed, through the bonding layer 17, to the surface of the first substrate 13 on which the first electrode 11 is formed. In this case, the second substrate 14 having the second electrode 12, and the bonding layer 17 may be perforated beforehand to form respective through holes, and may be thereafter stacked onto the first substrate 13.

As a result of the configuration described above, the first electrode 11 on the first substrate 13 and the second electrode 12 on the second substrate 14 are spaced apart from each other in the height direction at least by the thickness of the second substrate 14 plus the thickness of the bonding layer 17.

The via hole 15 is formed in the substrate 14. In the second example illustrated in FIG. 2, an electrical connection point between the first electrode 11 and the second electrode 12 is determined in the same manner as in the first example shown in FIG. 1, and the second substrate 14 is perforated with a prescribed diameter to a depth reaching the first electrode 11 to form the via hole 15. At this stage, the first electrode 11 is exposed in the via hole 15.

In the second example, similarly to the first example, the conductive ink used in the invention is applied to the via hole 15. In the second example of the metal film forming method, the first electrode 11 and the second electrode 12 may be connected together with high reliability through a metal film 16 formed on the inner surface in the via hole 15. Further, the bonding layer 17 allows the first substrate 13 and the second substrate 14 to be fixed to each other with higher reliability.

In the first example and the second example, highly reliable connection can be established between electrodes. In the event that any connection failure occurs during operation, the connection can be repaired simply by applying and heating the conductive ink again in the similar manner.

### [Conductive Ink]

The conductive ink used in the invention will be described.

The conductive ink used in the invention is a composition containing a metal salt and a reducing agent, namely, a reductive composition. The conductive ink may further contain metal fine particles. The conductive ink may further contain a solvent.

The conductive ink in the invention is defined as an ink that forms a conductive metal film by undergoing reduction reaction. That is, the ink may have or may not have conduction properties before the reduction reaction.

The conductive ink may be applied into the holes by any of various coating methods and printing methods. The conductive ink that has been coated or printed forms a metal film by being heated. When electrodes have been formed adjacent to the hole, the metal film serves as a conduction portion therebetween.

For example, heating in a non-oxidizing atmosphere induces the reduction reaction of the metal salt in the conductive ink, and the metal salt is precipitated in the form of metal fine particles onto the inner surface in the hole to serve as the nucleus for further progress of the reduction reaction of the metal salt. In this manner, a metal film is formed along the inner surface in the hole. The metal film thus formed exhibits high adhesion with respect to electrodes and realizes low contact resistance. By adjusting the viscosity of the conductive ink, the conductive ink may be applied into the holes without trapping bubbles inside the holes while ensuring that the amount of the ink supplied is enough to form metal films on the inner surface in the holes. As a result, the metal film on the inner surface in the hole achieves highly reliable connection between separate electrodes.

The components in the conductive ink will be described below.

### [Metal Salts]

The metal salt is such that the metal ions are reduced by the reducing agent present in the conductive ink to form the metal itself that serves as a conduction portion exhibiting conduction properties. When, for example, the metal salt is a copper salt, the copper ions present in the copper salt are reduced by the reducing agent to form metallic copper serving as a conduction portion having conduction properties.

Copper salts and silver salts are preferable as the metal salts in the conductive ink.

The copper salts are not particularly limited and may be any compounds containing copper ions. Examples of the copper salts include salts composed of a copper ion and at least one selected from inorganic anions and organic anions. From the viewpoint of solubility, it is preferable to use at least one selected from copper carboxylate salts, copper hydroxide and copper/acetylacetone derivative complex salts. When the metal film is formed to connect a plurality of electrodes, it is preferable to use a salt of the same metal as the metal constituting the electrodes in order to obtain high conduction reliability between the electrodes.

Preferred examples of the copper carboxylate salts include copper salts of aliphatic carboxylic acids such as copper acetate, copper trifluoroacetate, copper propionate, copper butyrate, copper isobutyrate, copper 2-methylbutyrate, copper 2-ethylbutyrate, copper valerate, copper isovalerate, copper pivalate, copper hexanoate, copper heptanoate, copper octanoate, copper 2-ethylhexanoate and copper nonanoate; copper salts of dicarboxylic acids such as copper malonate, copper succinate and copper maleate; copper salts of aromatic carboxylic acids such as copper benzoate and copper salicylate; and copper salts of organic acids having carboxyl groups such as copper formate, copper hydroxyacetate, copper glyoxylate, copper lactate, copper oxalate, copper tartrate, copper malate and copper citrate. Copper formate may be an anhydride or a hydrate. Examples of copper formate hydrates include the tetrahydrate.

Preferred examples of the copper/acetylacetone derivative complex salts include copper acetylacetonate, copper 1,1,1-trimethylacetylacetonate, copper 1,1,1,5,5,5-hexamethylacetylacetonate, copper 1,1,1-trifluoroacetylacetonate and copper 1,1,1,5,5,5-hexafluoroacetylacetonate.

Of these, copper hydroxide and copper carboxylate salts such as copper acetate, copper propionate, copper isobutyrate, copper valerate, copper isovalerate, copper formate, copper formate tetrahydrate and copper glyoxylate are preferable from the viewpoints of the solubility or dispersibility in the reducing agents or solvents, and also resistance characteristics of the obtainable conduction portions.

The silver salts are not particularly limited and any silver salts may be used. Examples include silver nitrate, silver acetate, silver acetylacetonate, silver benzoate, silver bromate, silver bromide, silver carbonate, silver chloride, silver citrate, silver fluoride, silver iodate, silver iodide, silver lactate, silver nitrite, silver perchlorate, silver phosphate, silver sulfate, silver sulfide and silver trifluoroacetate.

To suppress the migration of metal atoms in the conduction portions formed, a copper salt is preferably used in the conductive ink. Of the copper salts, reducible copper formate, copper acetate and copper hydroxide are more preferable, and reducible copper formate is still more preferable. The copper formate may be an anhydride or a tetrahydrate.

The content of the metal salt is preferably in the range of 0.01 mass % to 50 mass %, and more preferably 0.1 mass % to 30 mass % relative to the total mass of the conductive ink. When the content of the metal salt is in the range of 0.01 mass % to 50 mass %, the conductive ink may form metal films that stably serve as conduction portions having excellent conduction properties. In order for the metal film to exhibit a low resistance value, the content of the metal salt is preferably 0.01 mass % or more. The content of the metal salt is preferably 50 mass % or less in order to obtain a chemically stable conductive ink.

### [Reducing Agents]

In addition to the aforementioned metal salt that is a metal component, the conductive ink used in the invention contains a reducing agent for the purpose of reducing the metal ions of the metal salt into the elementary metal. The reducing agents are not particularly limited as long as having the reducing performance for the metal ions of the metal salt present in the conductive ink. Here, the reducing performance indicates the capability of reducing the metal ions of the metal salt present in the conductive ink.

Examples of the reducing agents include monomolecular compounds having at least one functional group selected from thiol group, nitrile group, amino group, hydroxyl group and hydroxycarbonyl group, and polymers having at least one heteroatom selected from nitrogen atom, oxygen atom and sulfur atom in the molecular structure.

Examples of the monomolecular compounds include alkanethiols, amines, hydrazines, monoalcohols, diols, hydroxylamines, α-hydroxyketones and carboxylic acids.

Examples of the polymers include polyvinylpyrrolidone, polyethyleneimine, polyaniline, polypyrrole, polythiophene, polyacrylamide, polyacrylic acid, carboxymethyl cellulose, polyvinyl alcohol and polyethylene oxide.

Of these, at least one selected from alkanethiols and amines is preferable in view of the solubility of the metal salt and easy removal during operation.

Examples of the alkanethiols include ethanethiol, n-propanethiol, i-propanethiol, n-butanethiol, i-butanethiol, t-butanethiol, n-pentanethiol, n-hexanethiol, cyclohexanethiol, n-heptanethiol, n-octanethiol and 2-ethylhexanethiol.

Examples of the amines include amine compounds, specifically, monoamine compounds such as ethylamine, n-propylamine, i-propylamine, n-butylamine, i-butylamine, t-butylamine, n-pentylamine, n-hexylamine, cyclohexylamine, n-heptylamine, n-octylamine, 2-ethylhexylamine, 2-ethylhexylpropylamine, 2-ethoxyethylamine, 3-ethoxypropylamine, n-nonylamine, n-decylamine, n-undecylamine, n-dodecylamine, n-tridecylamine, n-tetradecylamine, n-pentadecylamine, n-hexadecylamine, benzylamine and aminoacetaldehyde diethylacetal; diamine compounds such as ethylenediamine, N-methylethylenediamine, N,N′-dimethylethylenediamine, N,N,N′,N′-tetramethylethylenediamine, N-ethylethylenediamine, N,N′-diethylethylenediamine, 1,3-propanediamine, N,N′-dimethyl-1,3-propanediamine, 1,4-butanediamine, N,N′-dimethyl-1,4-butanediamine, 1,5-pentanediamine, N,N′-dimethyl-1,5-pentanediamine, 1,6-hexanediamine, N,N′-dimethyl-1,6-hexanediamine and isophoronediamine; and triamine compounds such as diethylenetriamine, N,N,N′,N″N″-pentamethyldiethylenetriamine, N-(aminoethyl)piperadine and N-(aminopropyl)piperadine.

Examples of the hydrazines include 1,1-di-n-butylhydrazine, 1,1-di-t-butylhydrazine, 1,1-di-n-pentylhydrazine, 1,1-di-n-hexylhydrazine, 1,1-dicyclohexylhydrazine, 1,1-di-n-heptylhydrazine, 1,1-di-n-octylhydrazine, 1,1-di-(2-ethylhexyl)hydrazine, 1,1-diphenylhydrazine, 1,1-dibenzylhydrazine, 1,2-di-n-butylhydrazine, 1,2-di-t-butylhydrazine, 1,2-di-n-pentylhydrazine, 1,2-di-n-hexylhydrazine, 1,2-dicyclohexylhydrazine, 1,2-di-n-heptylhydrazine, 1,2-di-n-octylhydrazine, 1,2-di-(2-ethylhexyl)hydrazine, 1,2-diphenylhydrazine and 1,2-dibenzylhydrazine.

Examples of the monoalcohols include methanol, ethanol, n-propyl alcohol, i-propyl alcohol, n-butyl alcohol, i-butyl alcohol, sec-butyl alcohol, pentanol, hexanol, heptanol, octanol, cyclohexanol, benzyl alcohol and terpineol.

Examples of the diols include ethylene glycol, propylene glycol, 1,2-butanediol, 1,2-pentanediol, 1,2-hexanediol, 2,3-butanediol, 2,3-pentanediol, 2,3-hexanediol, 2,3-heptanediol, 3,4-hexanediol, 3,4-heptanediol, 3,4-octanediol, 3,4-nonanediol, 3,4-decanediol, 4,5-octanediol, 4,5-nonanediol, 4,5-decanediol, 5,6-decanediol, 3-N,N-dimethylamino-1,2-propanediol, 3-N,N-diethylamino-1,2-propanediol, 3-N,N-di-n-propylamino-1,2-propanediol, 3-N,N-di-i-propylamino-1,2-propanediol, 3-N,N-di-n-butylamino-1,2-propanediol, 3-N,N-di-i-butylamino-1,2-propanediol and 3-N,N-di-t-butylamino-1,2-propanediol.

Examples of the hydroxylamines include N,N-diethylhydroxylamine, N,N-di-n-propylhydroxylamine, N,N-di-n-butylhydroxylamine, N,N-di-n-pentylhydroxylamine and N,N-di-n-hexylhydroxylamine.

Examples of the α-hydroxyketones include hydroxyacetone, 1-hydroxy-2-butanone, 3-hydroxy-2-butanone, 1-hydroxy-2-pentanone, 3-hydroxy-2-pentanone, 2-hydroxy-3-pentanone, 3-hydroxy-2-hexanone, 2-hydroxy-3-hexanone, 4-hydroxy-3-hexanone, 4-hydroxy-3-heptanone, 3-hydroxy-4-heptanone and 5-hydroxy-4-octanone.

The carboxylic acids are not particularly limited as long as having the reducing performance for the metal salt. Examples include formic acid, hydroxyacetic acid, glyoxylic acid, lactic acid, oxalic acid, tartaric acid, malic acid and citric acid.

The reducing agents may be used singly, or two or more kinds of reducing agents may be appropriately selected or combined in accordance with the type of the metal salt to be reduced. When, for example, copper formate is used as the metal salt, the reducing agent is preferably an amine compound, and more preferably any of 2-ethylhexylamine, 2-ethylhexylpropylamine, 2-ethoxyethylamine, 3-ethoxypropylamine and aminoacetaldehyde diethylacetal.

The content of the reducing agent is preferably in the range of 1 mass % to 99 mass %, and more preferably 10 mass % to 90 mass % relative to the total mass of the conductive ink. When the content of the reducing agent is in the range of 1 mass % to 99 mass %, the obtainable metal film exhibits excellent conduction properties. By controlling the content of the reducing agent to the range of 10 mass % to 90 mass %, the obtainable metal film may exhibit a low resistance value and achieve excellent adhesion with respect to electrodes.

### [Metal Fine Particles]

The conductive ink used in the invention may further contain metal fine particles in order to increase the rate of the reduction precipitation of the metal from the metal salt or to control the viscosity of the conductive ink.

The metal fine particles are not particularly limited. It is, however, preferable that the fine particles contain at least one metal selected from, for example, gold, silver, copper, platinum and palladium. These metals may be elementary metals or alloys with other metals. Preferred metal fine particles are at least one selected from gold fine particles, silver fine particles, copper fine particles, platinum fine particles, palladium fine particles and silver-coated copper fine particles.

Of these particles, metal fine particles containing at least one metal selected from silver, copper and palladium are preferable due to costs, easy availability and the catalytic performance in the formation of the conduction portions having conduction properties. Metal fine particles other than those described above are also usable. However, the use of the aforementioned metal fine particles is more preferable because when, for example, a copper salt is used as the metal salt, such other metal fine particles may be oxidized by the copper ions and may exhibit poor or no catalytic performance possibly to cause a decrease in the rate of the reduction precipitation of the metallic copper from the copper salt.

The average particle diameter of the metal fine particles is preferably in the range of 0.05 μm to 5 μm. In order to prevent the occurrence of oxidation reaction due to an increase in the activity of the metal surface and also to prevent the aggregation of the metal fine particles, the average particle diameter of the metal fine particles is preferably not less than 0.05 μm. To prevent the settling of the metal fine particles during long storage, the average particle diameter of the metal fine particles is preferably not more than 5 μm.

The average particle diameter of the metal fine particles may be measured as follows. The metal fine particles are observed with a microscope such as a transmission electron microscope (TEM), a field emission transmission electron microscope (FE-TEM) or a field emission scanning electron microscope (FE-SEM). With respect to the field of view observed, three regions are selected in which the metal fine particles have relatively uniform particle diameters, and the particles in these regions are photographed with the magnification best suited for the measurement of particle diameters. From the micrographs obtained, one hundred particles apparently having relatively uniform particle diameters are selected and the diameters thereof are measured with a length meter such as a ruler. The values obtained are divided by the measurement magnification to calculate the particle diameters, the results being arithmetically averaged. The standard deviation may be determined during the observation based on the numbers of the metal fine particles having respective particle diameters. The coefficient of variation (the CV value) may be calculated from the following equation based on the average particle diameter and the standard deviation.

CV value=Standard deviation/Average particle diameter×100(%)

The metal fine particles may be purchased or synthesized by a known method without limitation. Examples of the generally known synthesis methods include physical gas-phase synthesis methods (dry methods) such as sputtering and gas-phase deposition, and liquid-phase methods (wet methods) such as precipitating metal fine particles by the reduction of a metal compound solution in the presence of a surface protecting agent.

The purity of the metal fine particles is not particularly limited. In order to ensure that the metal film exhibits conduction properties, the purity is preferably not less than 95%, and more preferably not less than 99%.

For example, the content of the metal fine particles may be in the range of 0 mass % to 60 mass % relative to the total mass of the conductive ink. When the metal fine particles are used, the content thereof is preferably in the range of 1 mass % to 40 mass %, and more preferably 1 mass % to 20 mass %.

### [Solvents]

The conductive ink used in the invention preferably contains a solvent in order to attain an appropriate viscosity and thereby to improve productivity, and also in order to form uniform conduction portions having low resistivity.

The solvents should be such that the components in the conductive ink are dissolved or dispersed therein. Examples include organic solvents that are not involved in the reduction reaction of the metal salt. Specifically, the solvent may be one or a mixture of compatible two or more solvents selected from ethers, esters, aliphatic hydrocarbons and aromatic hydrocarbons.

Examples of the ethers include hexyl methyl ether, diethylene glycol dimethyl ether, diethylene glycol diethyl ether, triethylene glycol dimethyl ether, triethylene glycol diethyl ether, tetrahydrofuran, tetrahydropyran and 1,4-dioxane.

Examples of the esters include methyl formate, ethyl formate, butyl formate, methyl acetate, ethyl acetate, butyl acetate, methyl propionate, ethyl propionate, butyl propionate and γ-butyrolactone.

Examples of the aliphatic hydrocarbons include n-pentane, n-hexane, n-heptane, n-octane, n-nonane, n-decane, n-undecane, n-dodecane, cyclohexane and decalin.

Examples of the aromatic hydrocarbons include benzene, toluene, xylene, ethylbenzene, n-propylbenzene, i-propylbenzene, n-butylbenzene, mesitylene, chlorobenzene and dichlorobenzene.

Of these organic solvents, such solvents as hexyl methyl ether, diethylene glycol dimethyl ether and n-octane are particularly preferable because of easy controlling of the viscosity of the liquid conductive ink.

For example, the content of the solvent may be in the range of 0 mass % to 95 mass % relative to the total mass of the conductive ink. When the solvent is used, the content thereof is preferably in the range of 1 mass % to 70 mass %, and more preferably 10 mass % to 50 mass %.

### [Preparation of Conductive Inks]

The conductive ink may be prepared by mixing the components by any method without limitation. Exemplary methods include stirring with a stirring blade, stirring with a stirrer and a stirring bar, stirring with a boiler, ultrasonic stirring (with a homogenizer) and stirring with a wave rotor. In the case of stirring with a stirring blade, for example, the stirring conditions are such that the rotational speed of the stirring blade is usually in the range of 1 rpm to 4000 rpm, and preferably 100 rpm to 2000 rpm. In the case of mixing with a wave rotor, the rotational speed of the container is usually in the range of 10 to 100 rpm, and preferably 50 to 100 rpm.

The viscosity of the conductive ink may be controlled in accordance with the coating or printing method. The viscosity of the conductive ink is preferably not more than 1 Pa·s, more preferably not more than 0.2 Pa·s, and still more preferably not more than 0.1 Pa·s. The lower limit is not particularly limited, but may be 0.007 Pa·s, and preferably 0.01 Pa·s.

The viscosity of the conductive ink may be controlled in accordance with the coating or printing method by adjusting the type and the amount of the reducing agent, or the types and the amounts of the metal fine particles and the solvent that are used as required. When, for example, the conductive ink is applied with a dispenser, the viscosity of the ink is preferably 0.01 Pa·s to 1 Pa·s.

The conductive ink adjusted to a viscosity in the above range attains improved workability and may be coated or printed without trapping bubbles inside the holes. Thus, in the invention, such a conductive ink can form a metal film connecting a plurality of electrodes together with higher conduction reliability.

The viscosity is measured at a temperature of 20° C. and a shear rate of 10 sec⁻¹. The viscosity may be measured by any viscosity measurement method which may be performed at a specific shear rate such as a capillary method or a double cylinder method. For example, a cone/plate (E-type) viscometer is preferably used.

### EXAMPLES

Embodiments of the present invention will be described in further detail based on Examples hereinbelow without limiting the scope of the invention to such Examples. In the following Examples, “part(s)” indicates “part(s) by mass” unless otherwise mentioned.

[symbol]

Preparation of Conductive Inks

[symbol]

### Example A1

At room temperature, 20 parts of copper formate tetrahydrate and 80 parts of 2-ethylhexylamine were mixed with each other with a wave rotor at 50 rpm to give a copper ink having a viscosity of 0.1 Pa·s. The viscosity of the copper ink was measured with an E-type viscometer (RE-80/85L manufactured by TOKI SANGYO CO., LTD.) at a temperature of 20° C. and a shear rate of 10 sec⁻¹.

### Examples A2 to A7

Copper inks were prepared in the same manner as in Example A1, except that the metal salt and the reducing agent used in Example A1 were changed as described in Table 1, and also that a solvent was used in some of these Examples. The unit for the values describing the amounts of the metal salts, the reducing agents and the solvents in Table 1 is “parts”. The viscosities of the copper inks obtained are shown in Table 1.

TABLE 1

| | | Ex. A1 | Ex. A2 | Ex. A3 | Ex. A4 | Ex. A5 | Ex. A6 | Ex. A7 |
|---|---|---|---|---|---|---|---|---|
| Metal | Copper formate tetrahydrate | 20 | | 10 | 15 | | | |
| salts | Anhydrous copper formate | | | | | | 15 | 15 |
| | Copper hydroxide | | 10 | | | | | |
| | Copper acetate | | | | | 10 | | |
| Reducing | 2-Ethylhexylamine | 80 | | | | | | |
| agents | 2-Ethylhexylpropylamine | | | | | | 50 | 35 |
| | 3-Ethoxypropylamine | | 75 | 90 | | 80 | | |
| | 2-Ethoxyethylamine | | | | | | | 25 |
| | Aminoacetaldehyde diethylacetal | | | | 85 | | | |
| | Formic acid | | 15 | | | 10 | | |
| Solvents | Diethylene glycol dimethyl ether | | | | | | 35 | |
| | Hexyl methyl ether | | | | | | | 25 |

| | | | | | | | |
|---|---|---|---|---|---|---|---|
| Viscosity (Pa · s) | 0.1 | 0.015 | 0.01 | 0.02 | 0.015 | 0.05 | 0.02 |

[symbol]

Manufacturing and Evaluation of Printed Wiring Boards

[symbol]

### Example B1

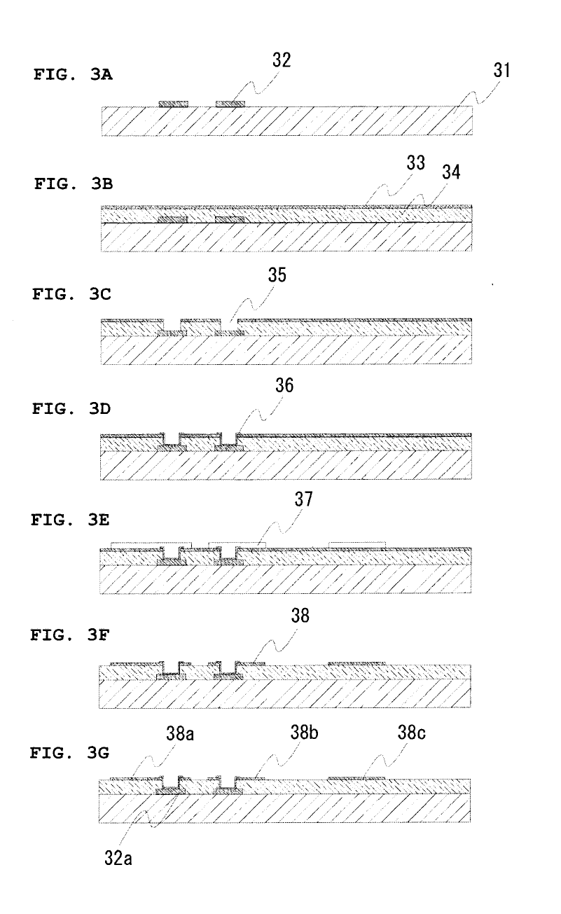

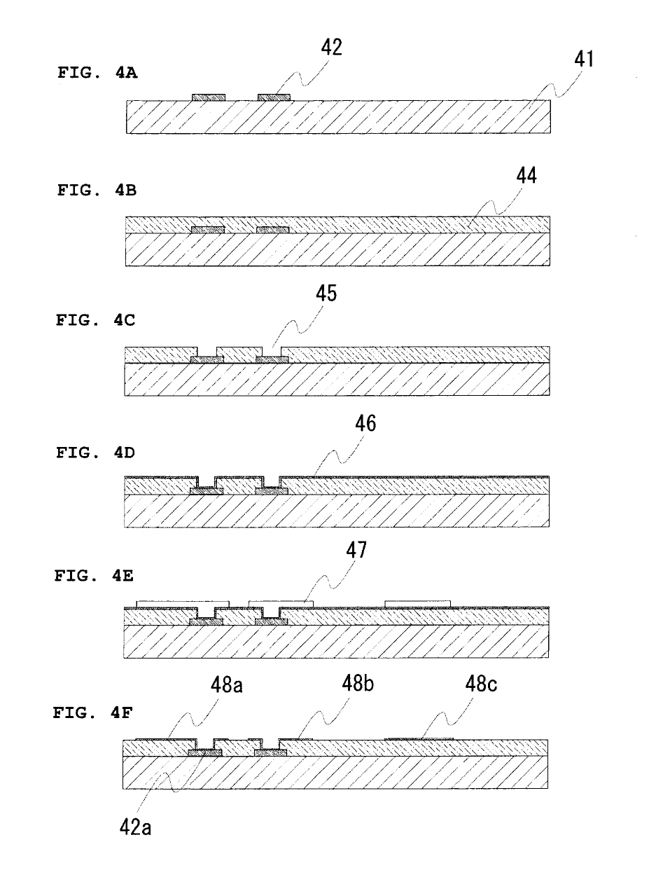

FIGS. 3A to 3G illustrate steps in a method for producing a metal film in Example B1.

A copper clad laminate (R1705 manufactured by Panasonic Corporation) was provided in which a copper foil having a thickness of 18 μm had been laminated on a glass epoxy resin substrate 31 having a thickness of 1 mm. As illustrated in FIG. 3A, the copper clad laminate was etched to form lower copper patterns 32 having a line with a width of 100 μm and a land with a diameter of 200 μm.

A resin-coated copper foil (MRG-200 manufactured by MITSUI MINING & SMELTING CO., LTD.) having a 65 μm thick insulating layer and a 5 μm thick copper foil was stacked onto the substrate 31 with a laminator. Consequently, as illustrated in FIG. 3B, a copper foil layer 33 and an insulating layer 34 were formed on the substrate 31.

As illustrated in FIG. 3C, etching was performed to remove the regions of the copper foil layer 33 and the insulating layer 34 stacked on the substrate 31 which were located at positions corresponding to central areas of the lands of the lower copper patterns 32. Specifically, such regions of the copper foil layer 33 were removed by a photolithographic step and an etching step in circular shapes with a diameter of 100 μm. Subsequently, the insulating layer 34 exposed as a result of the etching of the copper foil layer 33 was removed with a carbon dioxide laser (GTX-605 manufactured by Mitsubishi Electric Corporation) until the lower copper patterns 32 were exposed. Thus, via holes 35 reaching the lands were formed, the via holes 35 having a diameter of the openings of 100 μm. Further, the substrate was soaked in a permanganic acid liquid to remove organic matters that had become attached on the sidewalls of the via holes 35 and organic matters adhering to the land electrode surface exposed at the bottoms in the via holes 35.

The copper ink described in Example A1 was applied with a dispenser (non-contact jet dispenser SHOTMASTER 200DS manufactured by Musashi Engineering, Inc.) to fill the via holes 35. The nozzle diameter used was 32 gauge.

After the application of the copper ink, the substrate was treated in a nitrogen atmosphere at 170° C. for 10 minutes. Consequently, as illustrated in FIG. 3D, conductive layers 36 having a thickness of 0.5 to 1.0 μm were formed on the inner surface in the via holes 35.

As illustrated in FIGS. 3E and 3F, a photoresist layer 37 was patterned on the copper foil layer 33, and the exposed portions of the copper foil layer 33 were etched to form upper copper patterns 38.

As illustrated in FIG. 3G, measurements with digital multimeter Keithley 2000 showed that the insulation resistance between the upper copper patterns 38b and 38c (the minimum distance between the electrodes: 50 μm) was not less than 10 MΩ and the resistance to conduction between the upper copper pattern 38a and the lower copper pattern 32a was not more than 10Ω. Similar results were obtained when the procedures of Example B1 were performed using any of the copper inks obtained in Examples A2 to A7 instead of the copper ink obtained in Example A1.

### Example B2

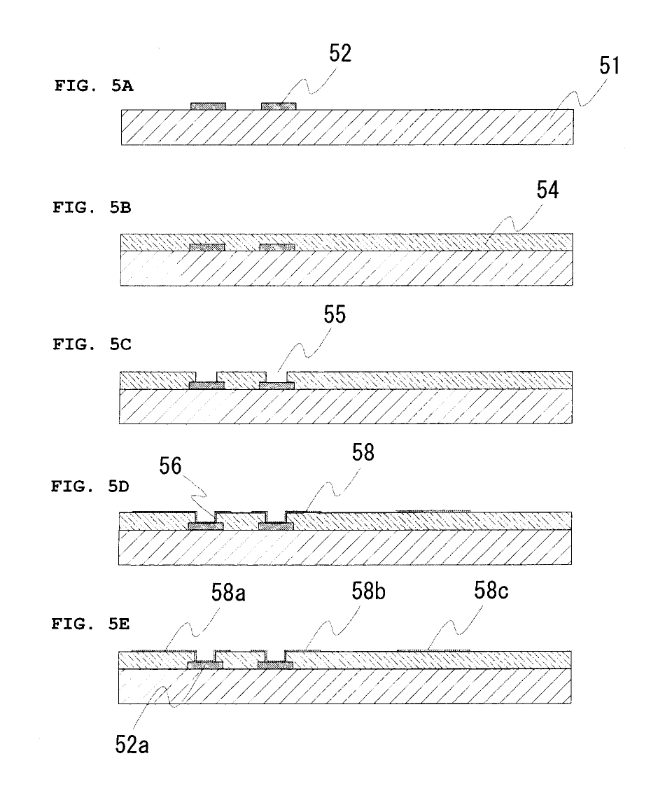

FIGS. 4A to 4F illustrate steps in a method for producing a metal film in Example B2.

A copper clad laminate (R1705 manufactured by Panasonic Corporation) was provided in which a copper foil having a thickness of 18 μm had been laminated on a glass epoxy resin substrate 41 having a thickness of 1 mm. As illustrated in FIG. 4A, the copper clad laminate was etched to form lower copper patterns 42 having a line with a width of 100 μm and a land with a diameter of 200 μm.

A resin layer with a thickness of 70 μm (ABF-GX13 manufactured by Ajinomoto Fine-Techno Co., Inc.) was stacked onto the substrate 41 with a laminator. Consequently, as illustrated in FIG. 4B, an insulating layer 44 was formed on the substrate 41.

As illustrated in FIG. 4C, the regions of the insulating layer 44 stacked on the substrate 41 which were located at positions corresponding to central areas of the lands of the lower copper patterns 42 were removed with a carbon dioxide laser (GTX-605 manufactured by Mitsubishi Electric Corporation) to form via holes 45 reaching the lands, the via holes 45 having a diameter of the openings of 100 μm. Further, the substrate was soaked in a permanganic acid liquid to remove organic matters that had become attached on the sidewalls of the via holes 45 and organic matters adhering to the land electrode surface exposed at the bottoms in the via holes 45.

The copper ink described in Example A1 was applied to fill the via holes 45 and also onto the surface of the insulating layer 44 by a bar coating method. The application conditions were such that the copper ink was coated at a bar speed of 5 cm/sec with a spacer thickness of 0.1 mm.

Thereafter, the substrate coated with the copper ink was treated in a nitrogen atmosphere at 170° C. for 10 minutes. Consequently, as illustrated in FIG. 4D, a conductive layer 46 having a thickness of 0.5 to 1.0 μm was formed on the inner surface in the via holes 45 and the surface of the insulating layer 44.

As illustrated in FIG. 4E, a photoresist layer 47 was patterned on the conductive layer 46, and the exposed portions of the conductive layer 46 were etched to form upper copper patterns 48.

As illustrated in FIG. 4F, measurements with digital multimeter Keithley 2000 showed that the insulation resistance between the upper copper patterns 48b and 48c (the minimum distance between the electrodes: 30 μm) was not less than 10 MΩ and the resistance to conduction between the upper copper pattern 48a and the lower copper pattern 42a was not more than 10Ω. Similar results were obtained when the procedures of Example B2 were performed using any of the copper inks obtained in Examples A2 to A7 instead of the copper ink obtained in Example A1.

### Example B3

FIGS. 5A to 5E illustrate steps in a method for producing a metal film in Example B3.

A copper clad laminate (R1705 manufactured by Panasonic Corporation) was provided in which a copper foil having a thickness of 18 μm had been laminated on a glass epoxy resin substrate 51 having a thickness of 1 mm. As illustrated in FIG. 5A, the copper clad laminate was etched to form lower copper patterns 52 having a line with a width of 100 μm and a land with a diameter of 200 μm.

A resin layer with a thickness of 70 μm (ABF-GX13 manufactured by Ajinomoto Fine-Techno Co., Inc.) was stacked onto the substrate 51 with a laminator. Consequently, as illustrated in FIG. 5B, an insulating layer 54 was formed on the substrate 51.

As illustrated in FIG. 5C, the regions of the insulating layer 54 stacked on the substrate 51 which were located at positions corresponding to central areas of the lands of the lower copper patterns 52 were removed with a carbon dioxide laser (GTX-605 manufactured by Mitsubishi Electric Corporation) to form via holes 55 reaching the lands, the via holes 55 having a diameter of the openings of 100 μm. Further, the substrate was soaked in a permanganic acid liquid to remove organic matters that had become attached on the sidewalls of the via holes 55 and organic matters adhering to the land electrode surface exposed at the bottoms in the via holes 55.

The copper ink described in Example A1 was applied with a dispenser (non-contact jet dispenser SHOTMASTER 200DS manufactured by Musashi Engineering, Inc.) to fill the via holes 55 and also to form patterns having an L/S ratio of 200 μm/200 μm on the surface of the insulating layer 54. The nozzle diameter used was 32 gauge.

Thereafter, the substrate coated with the copper ink was treated in a nitrogen atmosphere at 170° C. for 10 minutes. Consequently, as illustrated in FIG. 5D, conductive layers 56 having a thickness of 0.5 to 1.0 μm were formed on the inner surface in the via holes 55, and upper copper patterns 58 having a thickness of 0.5 to 1.0 μm were formed on the insulating layer 54.

As illustrated in FIG. 5E, measurements with digital multimeter Keithley 2000 showed that the insulation resistance between the upper copper patterns 58b and 58c (the minimum distance between the electrodes: 200 μm) was not less than 10 MΩ and the resistance to conduction between the upper copper pattern 58a and the lower copper pattern 52a was not more than 10Ω. Similar results were obtained when the procedures of Example B3 were performed using any of the copper inks obtained in Examples A2 to A7 instead of the copper ink obtained in Example A1.

### INDUSTRIAL APPLICABILITY

The metal film forming method of the invention can form metal films that exhibit strong adhesion with respect to the inner surface in holes and to electrodes, and can also establish a connection between electrodes adjacent to the hole with high conduction reliability. Further, the electrical connections formed by the inventive method may be repaired easily. Thus, the method of the invention may be used in a wide range of applications including, for example, the manufacturing of circuit boards such as multilayer wiring boards and the manufacturing of electronic devices using such circuit boards.

### REFERENCE SIGNS LIST

1, 11 FIRST ELECTRODE
2, 12 SECOND ELECTRODE
3, 13 FIRST SUBSTRATE
4, 14 SECOND SUBSTRATE
5, 15 VIA HOLE
6, 16 METAL FILM
17 BONDING LAYER
31, 41, 51 SUBSTRATE
32, 42, 52 LOWER COPPER PATTERNS
33 COPPER FOIL LAYER
34, 44, 54 INSULATING LAYER
35, 45, 55 VIA HOLE
36, 46, 56 METAL FILM (CONDUCTIVE LAYER)
37, 47 PHOTORESIST LAYER
38, 48, 58 UPPER COPPER PATTERNS
100 SUBSTRATE
101 CORE SUBSTRATE
102 INSULATING LAYER
201 HOLE
202 SIDEWALL IN HOLE
203 BOTTOM (BLOCKED END) IN HOLE
204 OPENING OF HOLE

What is claimed is:

1. A metal film forming method comprising a step of heating a perforated substrate having a hole while a surface of the substrate adjacent to the hole is in contact with a conductive ink comprising a metal salt and a reducing agent.

2. The metal film forming method according to claim 1, wherein the viscosity of the conductive ink is not more than 1 Pa·s.

3. The metal film forming method according to claim 1, wherein the substrate has a bottomed hole having an opening on one side and a blocked end on the other side.

4. The metal film forming method according to claim 3, wherein the substrate is a stack including a plurality of layers, the opening is defined by a through hole disposed in a first layer, and the blocked end is defined by a second layer.

5. The metal film forming method according to claim 3, wherein the diameter of the opening is 1 to 1000 μm.

6. The metal film forming method according to claim 1, wherein the substrate has at least one electrode formed adjacent to the hole.

7. The metal film forming method according to claim 1, wherein the metal salt is a copper salt.

8. The metal film forming method according to claim 7, wherein the copper salt is at least one selected from copper formate and copper formate tetrahydrate.

9. The metal film forming method according to claim 1, wherein the reducing agent is at least one selected from alkanethiols, amines, hydrazines, monoalcohols, diols, hydroxylamines, α-hydroxyketones and carboxylic acids.

10. The metal film forming method according to claim 1, wherein the conductive ink further comprises a solvent.

11. The metal film forming method according to claim 1, wherein the heating is performed in a non-oxidizing atmosphere at a temperature in the range of 50° C. to 500° C.

12. The metal film forming method according to claim 1, wherein the conductive ink is brought into contact with the surface of the substrate adjacent to the hole by a coating method or a printing method.

13. The metal film forming method according to claim 1, wherein the hole is a via hole formed in a multilayer wiring board, a through silicon via formed in a semiconductor substrate, or a via hole formed in a multilayer wiring layer stacked on a semiconductor substrate.

14. The metal film forming method according to claim 1, wherein the metal film is a capacitor electrode for constituting a capacitor cell of a dynamic random access memory.

15. A conductive ink comprising a metal salt and a reducing agent, wherein the conductive ink is used in the metal film forming method described in claim 1.

16. The conductive ink according to claim 15, having a viscosity of not more than 1 Pa·s.

17. A multilayer wiring board having a metal film on a surface adjacent to a via hole, the metal film being formed from the conductive ink described in claim 15.

18. A semiconductor substrate having a metal film on a surface adjacent to a through silicon via disposed in the semiconductor substrate or on a surface adjacent to a via hole disposed in a multilayer wiring layer stacked on the semiconductor substrate, the metal film being formed from the conductive ink described in claim 15.

19. A capacitor cell of a dynamic random access memory, having a capacitor electrode formed from the conductive ink described in claim 15.
